(19) United States
(12) Patent Application Publication
(10) Pub. No.: US 2012/0060908 A1
(43) Pub. Date: Mar. 15, 2012

(54) LOCALIZED METAL CONTACTS BY LOCALIZED LASER ASSISTED CONVERSION OF FUNCTIONAL FILMS IN SOLAR CELLS

(75) Inventor: Douglas E. Crafts, Los Gatos, CA (US)

(73) Assignee: TETRASUN, INC., Saratoga, CA (US)

(21) Appl. No.: 13/265,641

(22) PCT Filed: Apr. 21, 2010
(86) PCT No.: PCT/US10/31881

§ 371 Date: Nov. 15, 2011

Related U.S. Application Data
(60) Provisional application No. 61/171,491, filed on Apr. 22, 2009.

(51) Int. Cl. H01L 31/0224; H01L 31/02; H01L 31/04; H01L 31/18

(52) U.S. Cl. 136/255; 438/72; 438/98; 136/256; 136/252; 257/E31.124; 257/E31.119

(57) ABSTRACT

A solar cell, including contact metallization formed using selective laser irradiation. An upper layer is formed in the solar cell including a material which can be selectively modified to electrical contacts upon laser irradiation. Selective laser irradiation is applied to at least one region of the upper layer to form at least one electrical contact in the layer. A remaining region of the upper layer may be a functional layer of the solar cell which need not be removed. The upper layer may be, e.g., a transparent, conductive film, and anti-reflective film, and/or passivation. The electrical contact may provide an electrically conductive path to at least one region below the upper layer of the solar cell.

### RELATED APPLICATION INFORMATION

This application claims the benefit of previously filed U.S. Provisional Application entitled “Localized Metal Contacts By Localized Laser Assisted Reduction Of Metal-Ions In Functional Films, And Solar Cell Applications Thereof,” filed 22 Apr. 2009 and assigned application No. 61/171,491; and is related to the commonly-assigned, previously filed U.S. Provisional Application entitled “High-Efficiency Solar Cell Structures and Methods of Manufacture,” filed 21 Apr. 2009 and assigned application No. 61/171,194; and to commonly-assigned, co-filed International Patent Application entitled “High-Efficiency Solar Cell Structures and Methods of Manufacture” filed as Attorney Docket No. 3304.001AWO and assigned application number ______. Each of these applications is hereby incorporated by reference herein in its entirety. All aspects of the present invention may be used in combination with any of the disclosures of the above-noted applications.

### TECHNICAL FIELD

The present invention relates to solar cells. More particularly, the present invention relates to improved solar cell metalized contacts, and methods of their manufacture.

### BACKGROUND OF THE INVENTION

In typical solar cells, solar radiation illuminates at least one surface of the solar cell (typically referred to as the front side). In order to achieve a high energy conversion efficiency of incident photons into electric energy, an efficient absorption of photons within a silicon wafer substrate is important. In certain cell structures (described further below) this is achieved by a low (parasitic) optical absorption of photons within all layers except the wafer itself. For the sake of simplicity the impact of the wafer's geometrical shape (a surface texture such as pyramids is usually formed on crystalline wafer surfaces or other modifications of a flat surface are applied) is not specifically addressed herein, because it is understood that the surfaces may be textured in any shape beneficial for improved solar cell efficiency.

The choice of layers and their composition plays an important role in solar cell fabrication. Typically the number of layers, and each layer's associated processing steps (pre-clean, semiconductor film deposition, patterning-etch, pre-clean, metal deposition, and metal pattern-etch; etc.) contribute to cell complexity and corresponding manufacturing costs. Metallization is a particularly important feature of solar cells, and the demanding economics of solar cell manufacturing and deployment dictate stringent controls in manufacturing costs, and optimization wherever possible.

### SUMMARY OF THE INVENTION

The present invention provides a solar cell structure and a method of manufacture which provide the benefits of low shadowing of the solar cell, commonly caused by excessive surface coverage from the metal electrodes, a high conductivity of the metal grid, and minimized carrier recombination underneath the metal contacts on, e.g., the front illuminated side of the cell, or any other side of the cell. The techniques disclosed enable use of multifunctional layers which also include integral electrical contacts, and manufacturing techniques which decrease the number of materials and processing steps needed, thereby reducing solar cell manufacturing costs.

The present invention addresses the requirement for reduced complexity and corresponding manufacturing costs and processing steps by selectively converting the electrical conductivity state of a single, e.g., deposited dielectric insulating film, using direct laser energy impingement on the film, to form solar cell electrical contacts and interconnects without multiple deposition and patterning steps.

In that regard, the present invention, in one aspect, is a solar cell including an upper layer that provides at least one function to the solar cell (e.g., transparent dielectric film, antireflective film, passivation, etc.); wherein the upper layer includes a material that can be converted into an electrically conductive contact using selective laser irradiation impingement. The resulting electrical contact provides, e.g., an electrically conductive path to at least one region below the upper layer of the solar cell through the dielectric insulator. Metal plating may be subsequently formed over the selectively formed electrically conductive contact.

In one example, the material comprises a metal-nitride composite material, and the impinging laser irradiation selectively oxidizes the nitride resulting in the conversion of the material from a dielectric insulator into an electrically conductive contact, in, e.g., an oxidizing environment containing gaseous oxygen.

In another example, the material comprises a metal-carbide composite material, and the impinging laser irradiation selectively modifies the oxidization state of the metal-carbide composite, resulting in the conversion of the material from a dielectric insulator into an electrically conductive contact, in, e.g., an oxidizing environment containing gaseous oxygen.

In another example, the material comprises metal ions, and the laser irradiation reduces metal resulting in the formation of the electrical contact, in, e.g., a reducing environment containing gaseous hydrogen or forming gas or methanol or ethanol.

The upper layer may be formed over an underlying doped region including a doped semiconductor material, wherein dopants in the upper layer are of the same dopant type as the doped semiconductor material. The laser irradiation causes diffusion of the upper dopants into the underlying doped region, wherein the transformed region of the thin film dielectric layer forms an electrical contact with the underlying doped region. As an example, aluminum forms a P-type dopant when diffused into a silicon substrate.

The disclosed structures, methods, and products formed by these methods, and all related techniques form part of the invention.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in combination with the accompanying drawings in which:

FIG. 1a depicts a partial cross-section of a solar cell on which selective laser irradiation is used on, e.g., an insulating dielectric upper layer material comprising, e.g., metal containing compounds, in accordance with an aspect of the present invention;

FIG. 1b depicts laser-exposed areas in selected areas are converted by laser irradiation, forming conductive metal contacts from the dielectric insulating material, and wherein the contacts directly contact a lower layer;

FIG. 1c depicts contacts which may penetrate into or even through the upper layer into a lower layer, if the metal containing compounds are of the same type of dopants as those in the lower layer;

FIG. 1d depicts the created contacts used as a seed layer for a thickening plating step;

FIG. 2a depicts a partial cross-section of a second type of solar cell on which selective laser irradiation is used on an upper layer comprising, e.g., metal containing compounds, in accordance with an aspect of the present invention;

FIG. 2b depicts laser-exposed areas in which conductive metal contacts are created;

FIG. 2c depicts the created contacts used as a seed layer for a subsequent thickening plating step;

FIG. 3a depicts a partial cross-section of a solar cell on which selective laser irradiation is used on an upper layer comprising, e.g., metal containing compounds, in accordance with an aspect of the present invention;

FIG. 3b depicts laser-exposed areas in which metal seed layer contacts are created in the upper surface of the material, forming isolated or buried conductors;

FIG. 3c depicts the created contacts used as a seed layer for a subsequent thickening plating step;

FIG. 4 depicts a completed finger/bus bar front-grid structure on the front light-facing side of a solar cell, created according to the principles of the present invention;

FIGS. 5a-b depict using varying intensities of laser energy irradiation used to create varying depths of electrical contact areas and/or interconnect lines in accordance with an aspect of the present invention, wherein some of the converted material penetrates fully through the material forming contacts to the substrate, while some of the material is only converted near the surface, forming interconnects which are isolated from the substrate, but may be electrically integrated with the contacts to the substrate; and

FIG. 6 depicts a partial cross section of a solar cell including an embedded interstitial contact/interconnect structure formed in accordance with an aspect of the present invention.

### DESCRIPTION OF THE INVENTION

The present invention is directed to effecting a local change of a solar cell's layer composition by laser irradiation, during which a metal contact to the underlying layer(s) or across the front surface is established through or embedded into, e.g., an insulating dielectric. In one embodiment, the metal contacts can be interconnected to form a continuous contact grid of, e.g., fingers and/or bus-bars.

This local change in chemical composition is achieved for films which comprise metal containing compounds, for example, aluminum nitride, titanium oxide, aluminum oxide, boron nitride, silicon carbide or silver containing transparent layers. Some of these materials can be transparent binary ceramics. Another exemplary class of materials includes transparent conductive oxides (TCOs) such as aluminum doped zinc oxide or fluorine doped tin oxide or indium tin oxide or zinc tin oxide, etc.

Many of these metallic compounds have ideal optical properties for solar cells, namely they have a wide band-gap (in the range of 6 eV), providing high optical transparency; and appropriate refractive index (in the range of 1.8-2.4), providing effective anti-reflective coatings for many types of solar cells in typical applications.

Moreover, these metal containing compound films can provide very effective surface passivation of the solar cell substrate and/or upper layers, thereby reducing surface interface states and resulting in low surface carrier recombination losses.

Therefore, this invention presents a very effective structure and method of formation of multi-functional films in solar cells.

In one embodiment, local change of the chemical film composition can convert the film from an insulator to a conductor through a thermally activated oxidation of, e.g., a metal-nitride compound or metal carbide compound, resulting in removal or change in relative concentration of the nitride, metal or other oxides in the resulting converted material, in which case an oxidizing environment such as in air or in pure oxygen may be required. Alternatively, the change in chemical film composition can involve a reduction of the metal containing compound to metal, and in those cases a reducing material may be required such as gaseous hydrogen or forming gas or liquids like ethanol or methanol.

In a certain embodiments of the invention, films containing metals that act as a p-type dopant in the adjacent semiconductor material are used on top of p-type semiconductor layers. For silicon as the semiconductor material, examples are aluminum, gallium or indium. This way an out diffusion of e.g., aluminum into the underlying region can be provoked by the laser treatment of the film and a localized p-type doping underneath the contacts is achieved. This doping reduces contact recombination. Accordingly, films containing metals that act as an n-type dopant in the adjacent semiconductor material are used on top of n-type semiconductor layers. For silicon as the semiconductor material, some examples are arsenic, antimony or bismuth. This way an out diffusion of e.g. bismuth into the adjacent region can be provoked by the laser treatment of the film and a localized n-type doping underneath the contacts is achieved.

More generally, the thin upper layer may be deposited over a thin film layer which is a doped semiconductor material, wherein the metal containing compounds in the thin upper layer are of the same dopant type as the thin film doped semiconductor material.

Alternatively, the thin upper layer may be deposited over a semiconductor substrate which contains a heavily doped surface region, wherein the metal containing compounds in the thin upper layer are of the same dopant type as the heavily doped surface region of the semiconductor substrate.

In either case, the laser irradiation may cause diffusion of metal into the underlying doped region of the substrate or into the underlying doped semiconductor thin layer. The solar cell may be heat treated after laser irradiation to cause diffusion of metal into the underlying doped region of the substrate or into the underlying doped semiconductor thin film layer.

The invention can be applied to many solar cell structures, including any of those listed in the above-incorporated patent applications. The following are merely examples, but the invention is not limited to these examples.

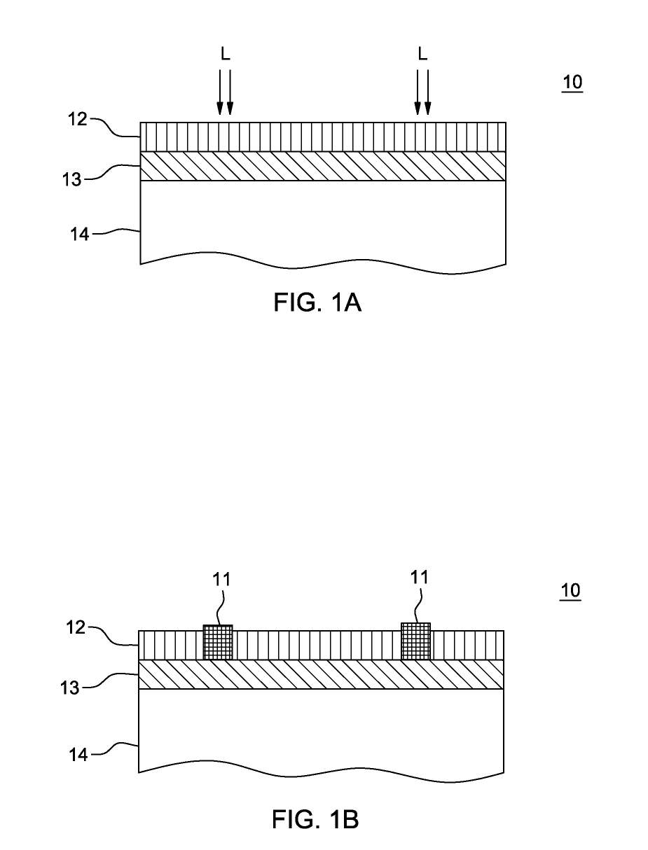

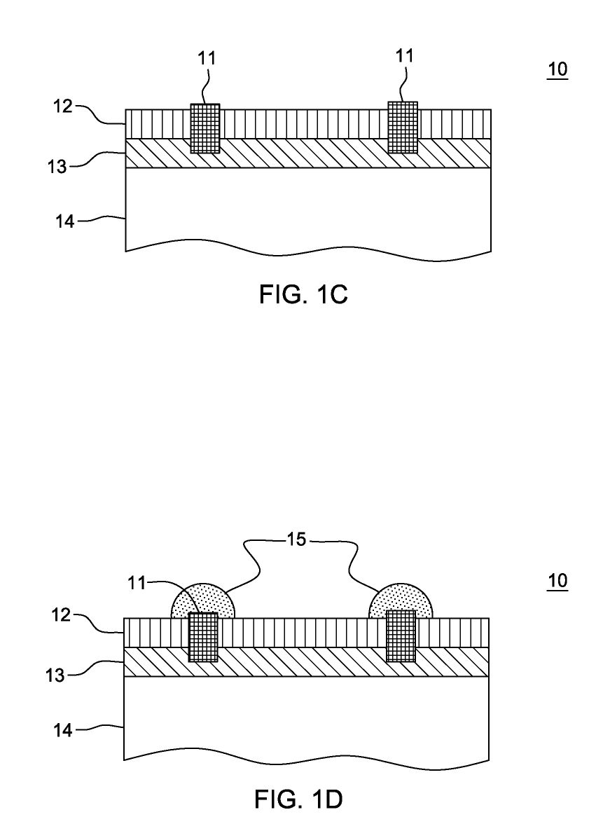

In accordance with the present invention, and with reference to the solar cell under process 10 of FIGS. 1a-d, selective laser irradiation, L, over previously-formed upper layer 12 converts the metal containing compound in layer 12, for example aluminum oxide, aluminum nitride, boron nitride, silicon carbide, to contact areas 11. Region 13 may be a diffusion region in the solar cell substrate (e.g., boron), and wafer 14 can be n- or p-type. The laser irradiation within the oxidizing environment thermally converts the metal containing compound to an electrically conductive metallic state, and contacts 11 to layer 13 are formed. Depending on the laser parameters, an aluminum silicon alloy can also be formed which results in a p-type doping in the contacted area.

With reference to FIG. 1c, the contact may penetrate into or even through the upper layer 12 into a lower layer 13, if metal containing compound comprises dopants of the same type as those in the lower layer (according to the diffusion process discussed above).

In a subsequent step (FIG. 1d) a plating process can be subsequently applied to form a plated conductor build-up layer 15, to increase the conductivity of the metal lines or inter-connect closely spaced discrete points into lines to form structures such as electrical electrodes and bus-bars forming a solar cell front-grid pattern (e.g., FIG. 4). In-situ heat treatment of the metal contacts formed by laser irradiation may also be employed.

The present invention can use Gaussian or top hat laser profiles. The formation of precise, e.g., top-hat laser profiles (e.g., known to be a controlled flat top profile rather than Gaussian) can be effected using very high power (>300 W) lasers to enable direct writing of repetitive features, with the machined features being defined by e.g., masks, translation stages, and/or scanners. Laser sources used may be high power multimode sources. The laser source wavelength, pulse width, repetition rate, and pulse energy are chosen to best suit the process requirements. Examples of such laser sources include diode pumped solid state Nd:YAG and Excimer lasers. Other examples include pulsed (Q-Switched) lasers or continuous wave lasers. The laser may be operated at a wavelength and pulse width at which laser energy effects the requisite material conversion into contacts. Used together, the laser power, beam profile, wavelength, pulse frequency are all parameters which can be used to adjust the laser absorption or coupling to a given metal containing compound film, and thereby adjust the depth profile of the converted material to form either full-depth contacts or isolated/buried interconnect lines, or other required structures.

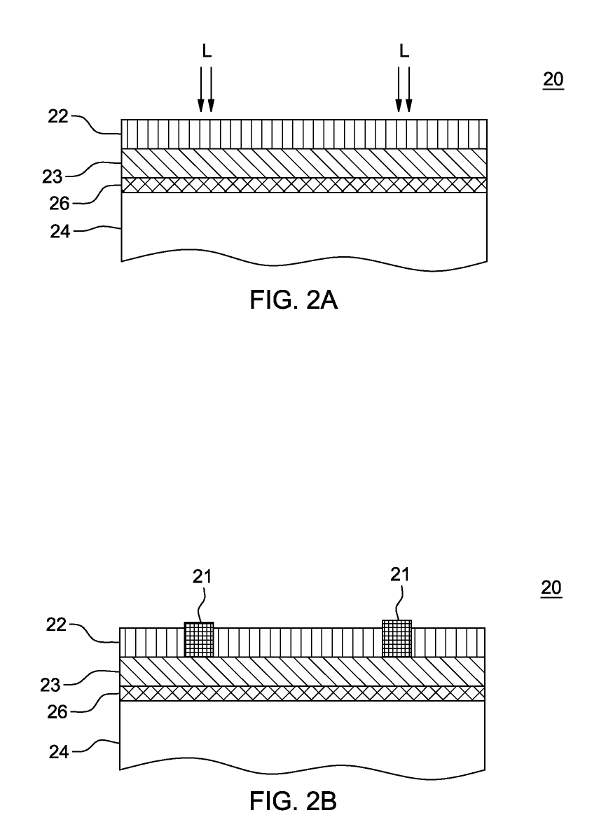

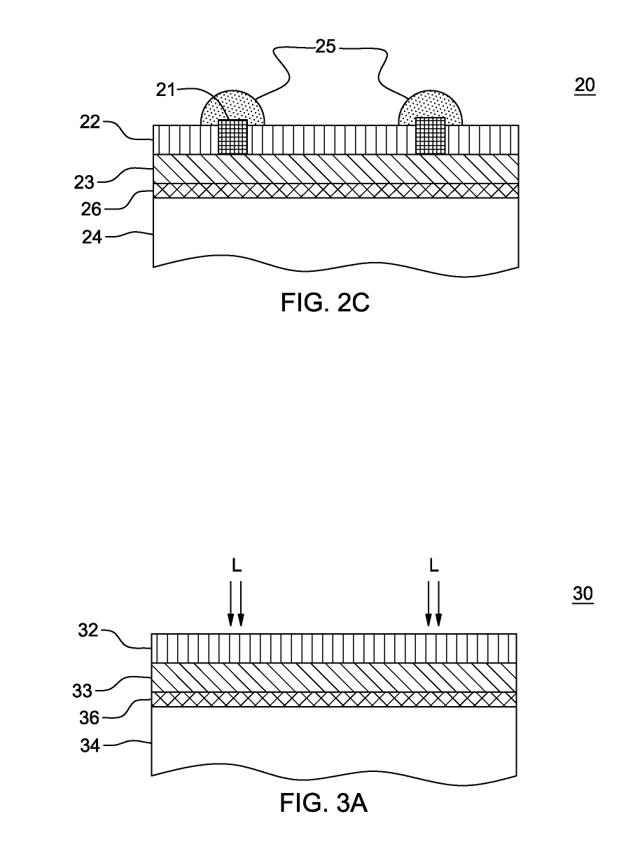

In accordance with another aspect of the present invention, and with reference to the solar cell under process 20 of FIGS. 2a-c, selective laser irradiation, L, over previously-deposited upper layer 22 (e.g., aluminum doped transparent conductive oxide) reduces the metal containing compound in upper layer 22, for example aluminum oxide, to contact areas 21. Region 23 may be p-type polycrystalline silicon layer on top of a thin thermal tunnel oxide 26, and wafer 24 can be n- or p-type.

The laser irradiation in one embodiment converts the metal containing compound material to a more metallic, electrically conductive contact material, and contacts 21 to the polysilicon layer 23 are formed. (As discussed above, not shown here, the metal may penetrate into or even through the upper layer 22 into lower layers 23.)

In a subsequent step (FIG. 2c) a plating process can be applied to form a plated conductor build-up layer 25, to increase the conductivity of the metal lines or inter-connect closely spaced discrete points into lines to form structures such as electrical electrodes and bus-bars (e.g., FIG. 4). In-situ heat treatment of the metal contacts formed by laser irradiation may also be employed.

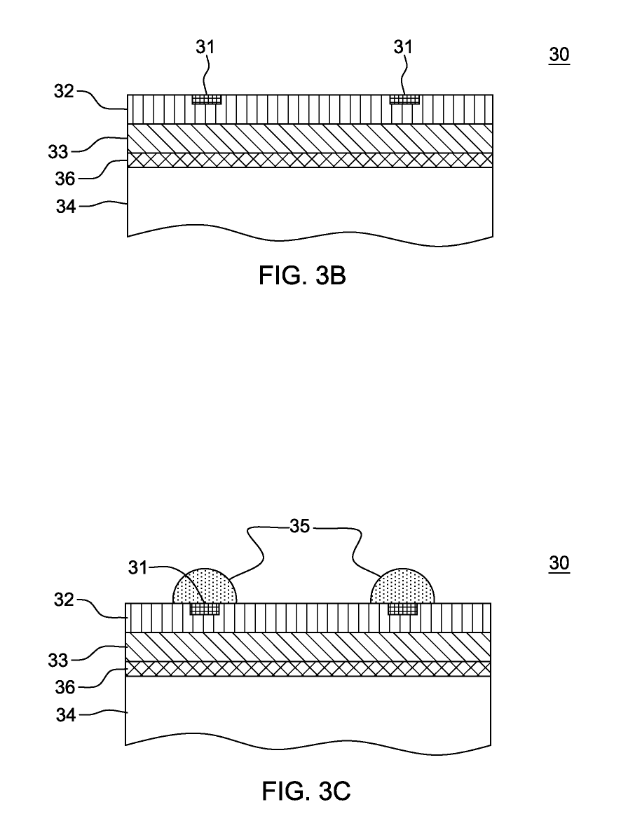

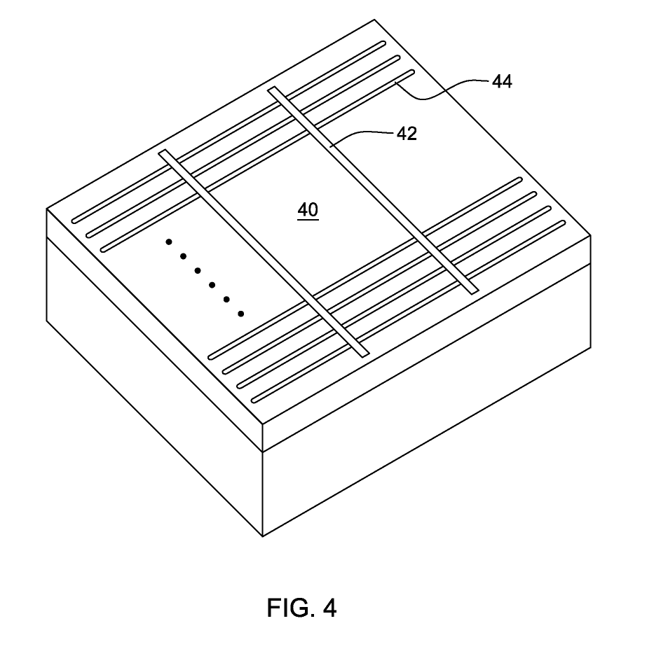

In accordance with another aspect of the present invention, and with reference to the solar cell under process 30 of FIGS. 3a-c, areas converted to contacts by the laser irradiation can act as a seed layer for the metal electrodes 35 which can be formed by a subsequent metal plating process (FIG. 3c). Selective laser irradiation, L, over previously-deposited upper layer 32 converts the metal containing compound in upper layer 32, for example aluminum oxide, aluminum nitride, boron nitride, silicon carbide, to seed areas 31. In this figure, the converted region penetrates only partially into the upper layer 32 forming electrically isolated interconnect lines contained within an otherwise, e.g., dielectric insulator. This is useful in the formation of a front grid pattern in a solar cell having an adequate level of electrical contact with the underlying solar cell substrate, while providing an electrical conduction path from the solar cell. Region 33 may be a p-type polycrystalline silicon layer on top of a thin thermal tunnel oxide 36, and wafer 34 can be n- or p-type.

As a result, no external alignment is necessary during subsequent metal plating (i.e., plating becomes self-aligned to the seed layer). Since the seed structure for the electrodes is embedded in the film, mechanical adhesion problems of the electrode are resolved. In-situ heat treatment of the metal contacts formed by laser irradiation may also be employed to reduce contact resistance by alloying the metallic compound or by forming intermetallic compounds with the plated metal.

The solar cell structure and formation techniques of the present invention have the benefit over the prior art that localized contacts can be created by the laser with much smaller feature sizes than standard printing or deposition techniques. The present invention also enables the formation of metal lines from a film (12, 22, 32) that is a functional film of the solar cell already, e.g. an antireflection coating, transparent film, surface passivation, etc., negating the need for other upper layers to be deposited on the cell upper surface. Therefore, the non-treated areas of the film (12, 22, 32) do not need to be patterned, removed or replaced, saving cost and manufacturing time.

FIG. 4 shows a solar cell 40 having a pattern of bus-bars 42 and fingers 44 forming a front-grid pattern on a surface thereof, formed in accordance with any of the above-described aspects of the present invention. In one example, thin contact lines of less than about 5-20 μm width, or discrete contact points of less than about 5-20 μm diameter are enabled by the present invention.

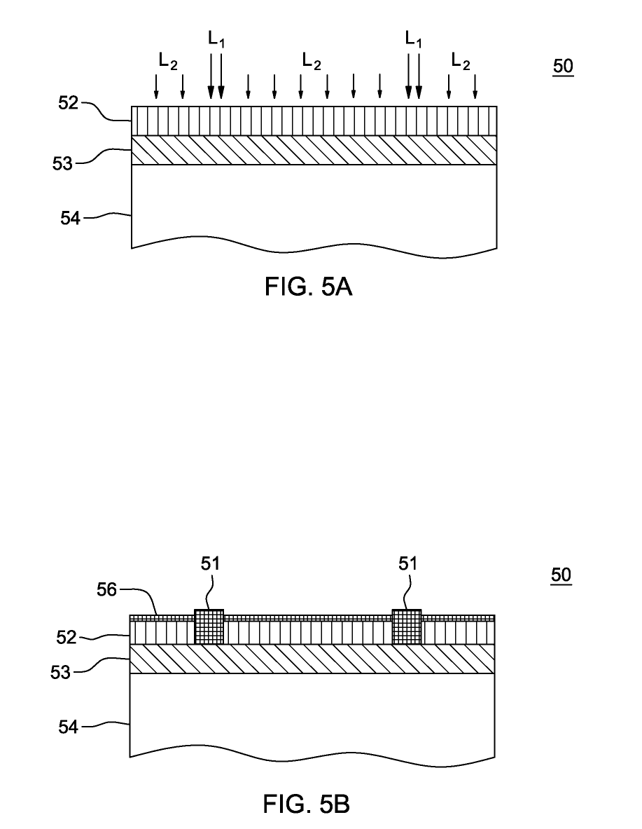

In accordance with another aspect of the present invention, and with reference to the solar cell under process 50 of FIGS. 5a-b, areas converted to contacts by the laser irradiation can be formed, in combination with shallower areas also processed by varying levels of laser irradiation intensity. For example, selective laser irradiation, L1, of a first intensity over previously-deposited upper layer 52 converts the metal containing compound in upper layer 52, for example aluminum oxide, to contact areas 51, for contacting lower layers 53 and 54. Another level of laser intensity, L2, is used to convert other areas into a shallower layer 56, to interconnect the contacts and to provide a path for conductance of current from the solar cell. In one example, the contact points and be formed in a random distribution at a density sufficient for the subsequent formation of the shallower buried interconnect lines to intercept or overlay a sufficient number of contact points to make adequate electrical contact to the underlying substrate with no need for a physical alignment of the interconnect lines to the contact points. The final structure may be a solar cell front grid pattern buried in a dielectric insulator, with through-contacts to the solar cell substrate.

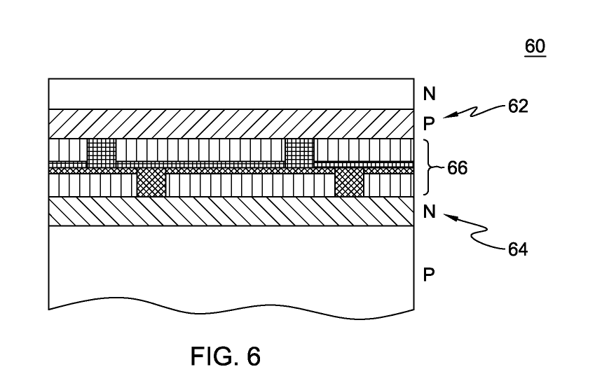

In accordance with another aspect of the present invention, and with reference to FIG. 6, an entire contact/grid structure 66 can be embedded interstitially between P-N junctions 62, 64 of a multi junction solar cell 60, forming the combination of insulating and serial-electrical interconnection between the adjacent junctions. As described in process 50, the contacts can be partially buried to make contact to an underlying substrate. Similarly, the contacts can be partially buried to make contact to a subsequently deposited overlaying layer. In this example, the overlaying layer could be the base of a subsequent solar sell junction, built upon a previously fabricated single junction solar cell, thereby both electrically insulating and interconnecting the two junctions in a serial P-N-P-N order. Moreover, two or more layers of the metal containing compound can be deposited to allow the direct laser formation of multiple-layer stacks of electrical conductors embedded in non-converted dielectric insulating material according to the methods previously described. The final structure is shown in FIG. 6, in which an embedded interconnect layer is shown between two junctions of a multi junction solar cell. Because of the high band gap of the metal compound film materials, they have high transparency, allowing the material to be embedded between junctions without unacceptable light absorption between the second and first junctions of the multi junction cell.

The term “contact” is used broadly herein to connote any type of conductive structure.

The term “metal containing compound” is used broadly herein to connote a material which can be converted into an electrically conductive contact according to the techniques of the present invention.

The present invention is applicable to contact formation on any side of a solar cell (e.g., front side, back side, etc.), or between junctions, buried within a multi junction solar cell.

One or more of the process control aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine embodying at least one program of instructions executable by the machine to perform the capabilities of the present invention can be provided.

The flow diagrams and steps disclosed herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

1. A method of forming at least one electrical contact in a layer of a solar cell, comprising:
forming a layer in the solar cell comprising a material which can be selectively modified to electrical contacts upon laser irradiation; and
applying selective laser irradiation to at least one area of the layer to thereby form at least one electrical contact in said area of the layer.

2. The method in accordance with claim 1, wherein a remaining region of the layer comprises a functional layer of the solar cell and need not be removed.

3. The method in accordance with claim 2, wherein the upper layer comprises a transparent layer.

4. The method in accordance with claim 3, wherein the upper layer comprises a transparent conductive film.

5. The method in accordance with claim 2, wherein the upper layer comprises an anti-reflective layer.

6. The method in accordance with claim 2, wherein the upper layer comprises a passivating dielectric film layer

7. The method in accordance with claim 2, wherein the material comprises a transparent insulating binary ceramic or other metallic composite material.

8. The method in accordance with claim 2, wherein the at least one electrical contact provides an electrically conductive path to at least one region below the upper layer of the solar cell.

9. The method in accordance with claim 2, wherein the material comprises a metal-nitride or metal-carbide composite material, and the laser irradiation oxidizes the nitride resulting in the formation of the at least one electrical contact.

10. The method in accordance with claim 2, wherein the laser irradiation is performed in an oxidizing environment.

11. The method in accordance with claim 10, wherein the oxidizing environment contains gaseous oxygen.

12. The method in accordance with claim 2, wherein the laser irradiation reduces metal into the at least one electrical contact.

13. The method in accordance with claim 12, wherein the laser irradiation is performed in a reducing environment.

14. The method of claim 13, wherein the reducing environment contains gaseous hydrogen or forming gas or methanol or ethanol.

15. The method in accordance with claim 2, further comprising plating the at least one electrical contact.

16. The method in accordance with claim 2, wherein the upper layer is formed over an underlying doped region including a doped semiconductor material.

17. The method of claim 16, wherein metal in the upper layer is of the same dopant type as the doped semiconductor material.

18. The method of claim 17, wherein the laser irradiation causes diffusion of the metal into the underlying doped region.

19. The method of claim 18, wherein the transformed region of the upper layer forms an electrical contact with the underlying doped region.

20. The method in accordance with claim 2, further comprising heat treating the solar cell after said applying selective laser irradiation to cause diffusion of metal ions into the underlying doped region.

21. A method of forming contact metallization in a solar cell, comprising:
depositing a layer which includes metal-nitride, metal-carbide, or metal-oxide compounds; and
applying laser irradiation over an area of the layer where metallization is required, to convert the oxidation state of composition of the compounds in said area of the layer, to electrically conductive metallic contacts.

22. A solar cell structure fabricated according to the method of claim 21.

23. A solar cell, comprising:
an upper layer that provides at least one function to the solar cell; and
wherein the upper layer includes a material that can be modified into an electrically conductive contact using laser irradiation.

24. The solar cell of claim 23, further comprising at least one electrical contact formed integrally in said upper layer.

25. The solar cell in accordance with claim 24, wherein the at least one electrical contact comprises a plurality of contacts randomly distributed allowing a front grid pattern to make alignment-free contact to a lower layer of the solar cell.

26. The solar cell in accordance with claim 24, wherein the electrical contact provides an electrically conductive path to at least one region below the upper layer of the solar cell.

27. The solar cell in accordance with claim 24, further comprising metal plating formed over the at least one contact.

28. The solar cell in accordance with claim 24, wherein the upper layer is transparent.

29. The solar cell in accordance with claim 24, wherein the upper layer material comprises an anti-reflective coating with an RI of between 1.8 and 2.4.

30. The solar cell in accordance with claim 24, wherein the upper layer comprises a passivating dielectric film.

31. The solar cell in accordance with claim 24, wherein the upper layer simultaneously performs multiple functions of transparency, surface passivation, electrical contact, electrical current distribution and seed-layer for a plated front grid pattern.

32. The solar cell in accordance with claim 24, wherein an interstitial contact and/or interconnect layer is formed to provide electrical contact between two or more junctions of a multi junction solar cell.

33. A solar cell structure fabricated according to the method of claim 2.
